(19) United States
(12) Patent Application Publication
(10) Pub. No.: US 2026/0304756 A1
(43) Pub. Date: Oct. 1, 2026

(54) Memory Circuitry And Methods Used In Forming Memory Circuitry

(71) Applicant: Micron Technology, Inc., Boise, ID (US)

(72) Inventors: Alyssa N. Scarbrough, Boise, ID (US); David Daycock, Boise, ID (US); Kolya Yastrebenetsky, Boise, ID (US); Sok Han Wong, Boise, ID (US)

(73) Assignee: Micron Technology, Inc., Boise, ID (US)

(21) Appl. No.: 19/097,040

(22) Filed: Apr. 1, 2025

(51) Int. Cl. H10B 12/00; H01L 21/762

(52) U.S. Cl. CPC H10B 12/488; H10B 12/0387; H10B 12/09; H10B 12/37; H10W 10/014; H10W 10/17

(57) ABSTRACT

A method used in forming memory circuitry comprises forming two memory-array regions individually comprising vertically-alternating insulative tiers and memory-cell tiers. An intervening region is laterally there-between. Access lines extend from the two memory-array regions into the intervening region and are horizontally spaced from one another. Immediately horizontally adjacent access lines connect with one another in the intervening region. A trench extends vertically through the vertically-alternating insulative and memory-cell tiers in the intervening region and is being spaced there-from. Through the trench, etching is conducted laterally through the immediately-horizontally-adjacent access lines to separate them from being connected with one another. An insulative wall is formed in the trench. Other embodiments, including method, are disclosed.

### TECHNICAL FIELD

Embodiments disclosed herein pertain to memory circuitry and to methods used in forming memory circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

Memory cells may be arranged or arrayed in several manners including, for example, in a vertical stack (e.g., along a vertical z direction) comprising a three-dimensional (3D) memory array region having horizontal tiers in which individual memory cells are received (e.g., arrayed in horizontal x and y directions). The stack in the 3D memory array region comprises vertically-alternating insulative tiers and conductive tiers (e.g., as part of memory-cell tiers) that extend into a connection region. The connection region may include individual “stairs” (alternately termed “steps” or “stair-steps”) that define contact regions of conductive lines of individual of the conductive tiers to which vertical conductive vias can contact to provide electrical access to/from those conductive lines. Alternately, electrical connection to the conductive lines in the individual conductive tiers may occur from vertical conductive vias that are aside a vertical stack of the conductive lines and extend laterally to directly electrically couple to one of the conductive lines.

### BRIEF DESCRIPTION OF THE DRAWINGS

FIG. 1 is a diagrammatic schematic of a DRAM memory array and peripheral circuitry in accordance with the prior art and in accordance with an embodiment of the invention.

FIG. 2 is an enlargement of a portion of FIG. 1.

FIGS. 3-12 are diagrammatic sectional views of constructions in accordance with embodiments of the invention.

FIGS. 13-30 are diagrammatic sequential sectional and/or enlarged views of the construction of FIGS. 3-12, or portions thereof or alternate and/or additional embodiments, in process in accordance with some embodiments of the invention.

### DETAILED DESCRIPTION OF EXAMPLE EMBODIMENTS

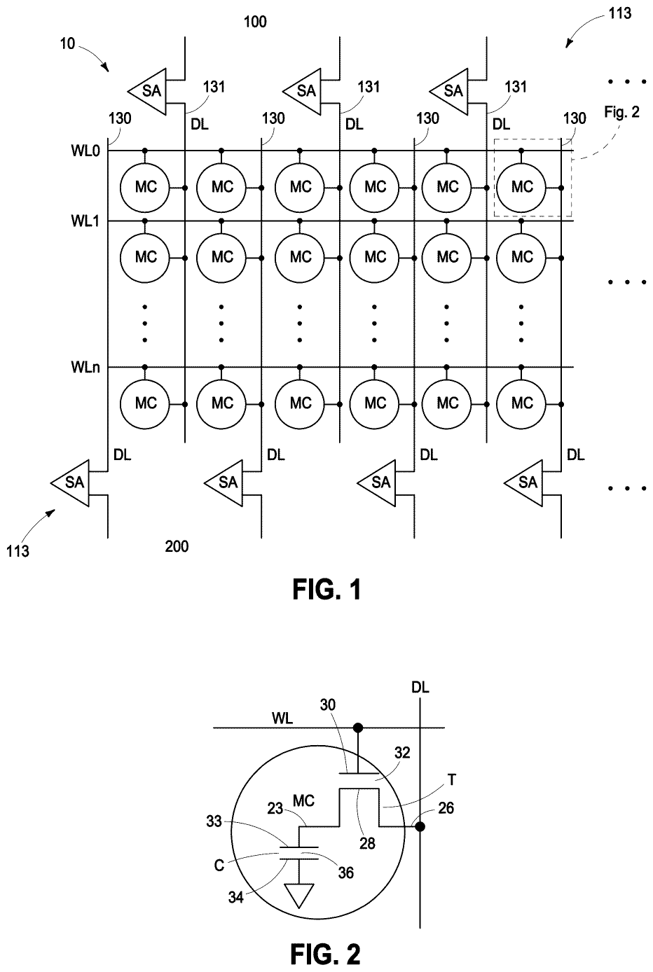

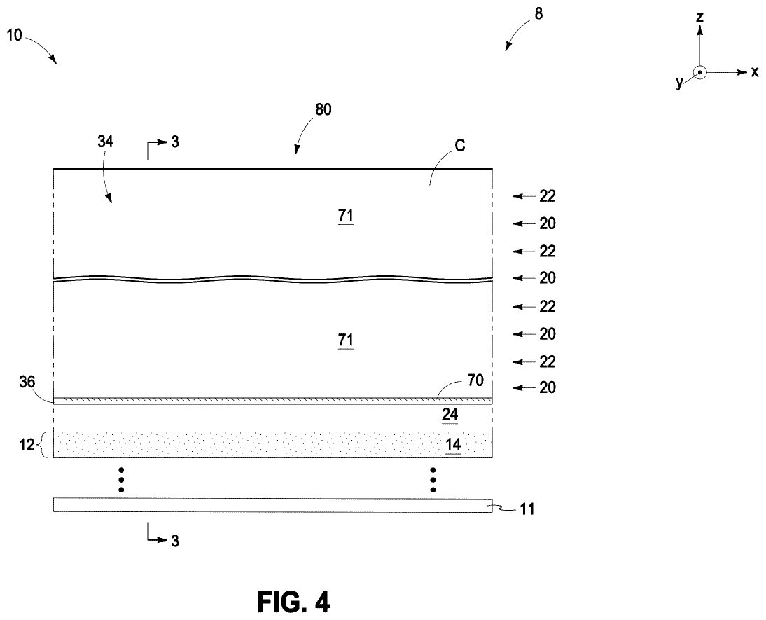

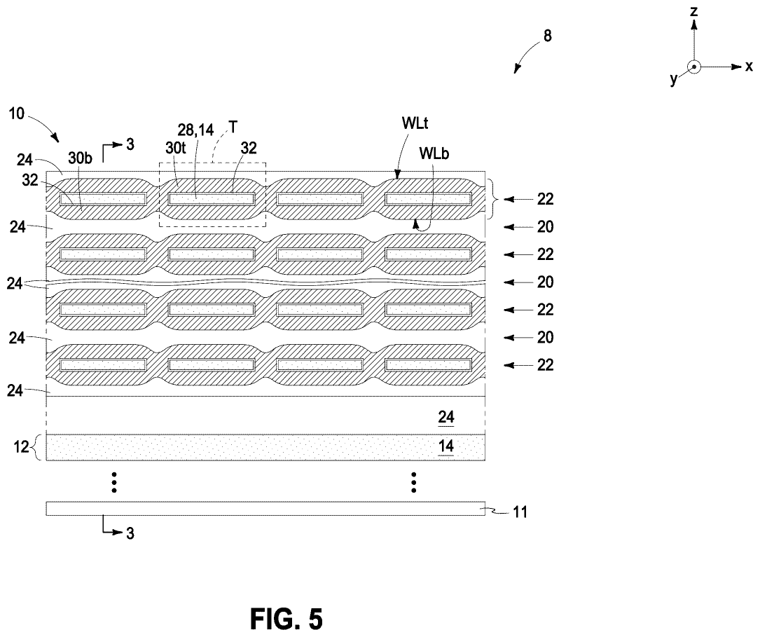

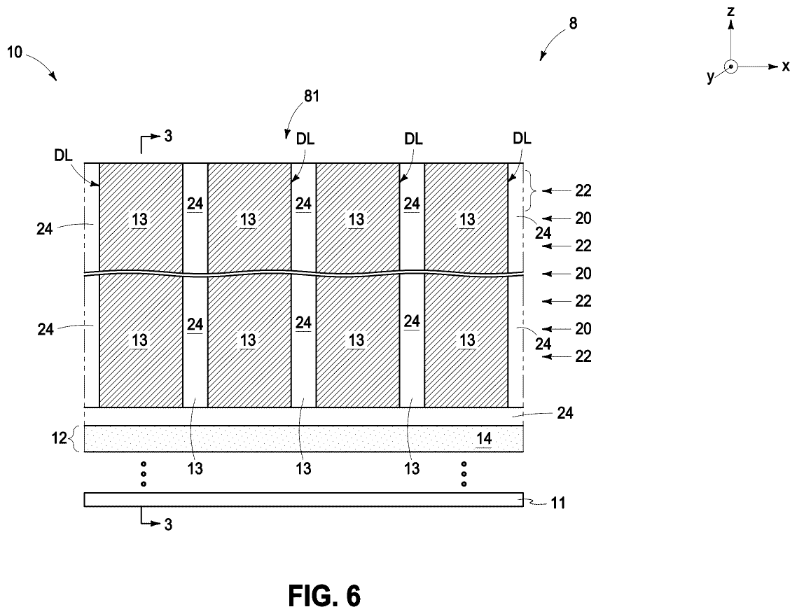

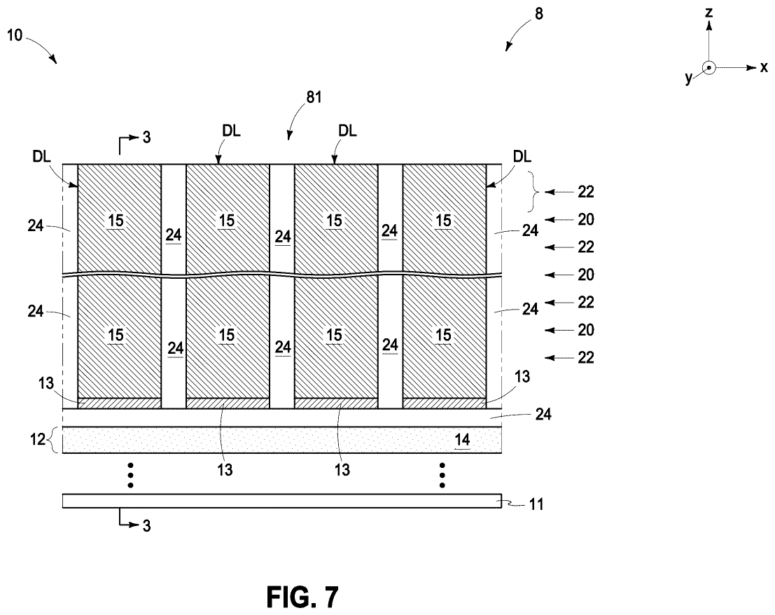

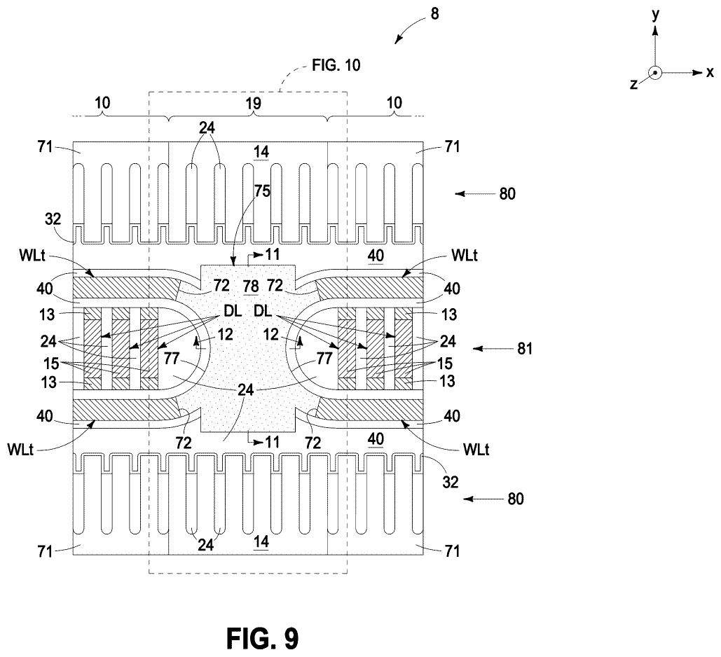

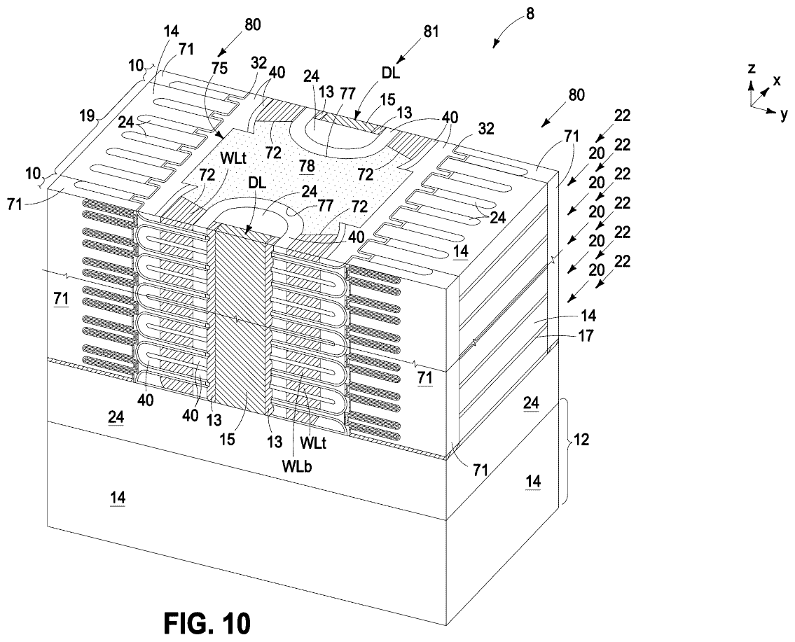

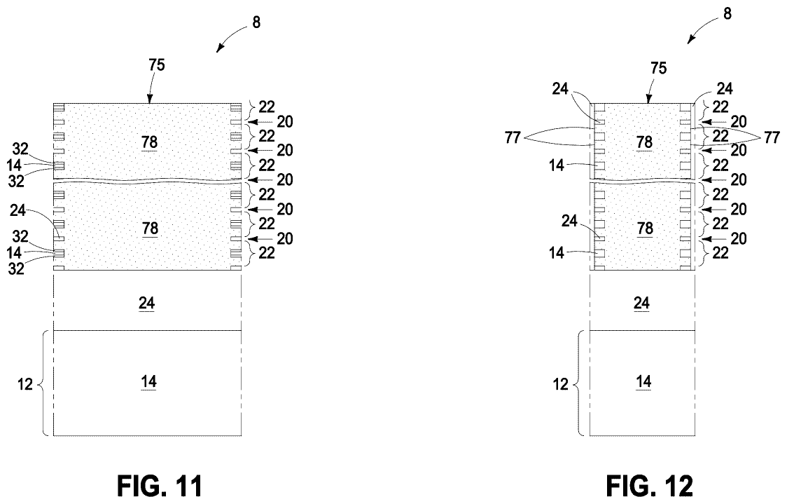

Embodiments of the invention encompass memory circuitry (e.g., DRAM), for example comprising vertically-stacked memory cells individually comprising a horizontal transistor and a capacitor electrically coupled therewith. Embodiments of the invention also encompass methods used in forming memory circuitry. Example structure embodiments are first described with reference to FIGS. 1-12.

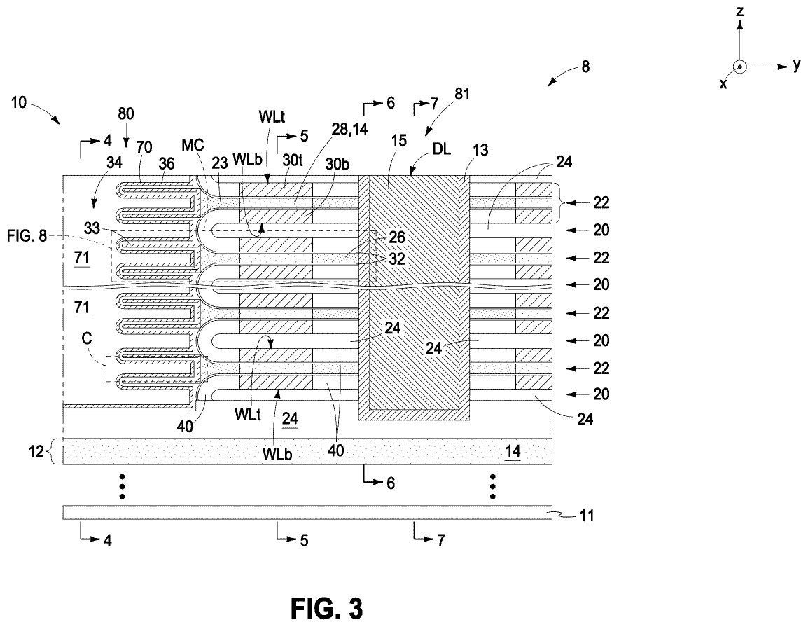

One example prior art schematic diagram of DRAM circuitry, and in accordance with an embodiment of the invention, is shown in FIGS. 1 and 2. FIG. 2 shows example memory cells MC individually comprising a transistor T and a capacitor C. One electrode of capacitor C is directly electrically coupled to a suitable potential (e.g., ground) and the other capacitor electrode is contacted with or comprises one of the source/drain regions of transistor T. The other source/drain region of transistor T is directly electrically coupled with a digitline/sense line 130 or 131 (also individually designated as DL). The gate of transistor T is directly electrically coupled with (e.g., comprises part thereof) a wordline/access line WL. FIG. 1 shows digitlines 130 and 131 extending from one of opposite sides 100 and 200 of a memory array area 10 into a peripheral circuitry area 113 that is aside memory array area 10. Digitlines 130 and 131 individually directly electrically couple with a sense amp SA on opposite sides 100 and 200 of array area 10 within peripheral circuitry area 113. Sense amps SA could be on only one side or all directly above or directly below memory array area 10. Non-schematic structure embodiments as shown herein in FIG. 3+have the wordlines/access lines running horizontally and the digitlines/sense lines running vertically.

Referring to FIGS. 3-12, an example fragment of a construction 8 comprises two memory-array regions 10 (e.g., individually constituting a “patch”) and an intervening region 19 laterally there-between, both of such being above a base substrate 11. Base substrate 11 comprises any one or more of conductive/conductor/conducting, semiconductive/semiconductor/semiconducting, and insulative/insulator/insulating (i.e., electrically herein) materials. Materials may be aside, elevationally inward, or elevationally outward of the FIG. 3-12-depicted materials. For example, other partially or wholly fabricated components of integrated circuitry may be provided somewhere above, about, or within base substrate 11. Control and/or other peripheral circuitry for operating components within a memory array may also be fabricated and may or may not be wholly or partially within a memory array or sub-array. Further, multiple sub-arrays may also be fabricated and operated independently, in tandem, or otherwise relative one another. As used in this document, a “sub-array” may also be considered as an array. Example construction 8 comprises a semiconductor substrate 12 (e.g., comprising semiconductor material 14 such as monocrystalline silicon) having insulative material 24 there-above (e.g., silicon dioxide and/or silicon nitride).

Memory-array regions 10 of example memory circuitry (e.g., that of or comprising construction 8) comprises vertically-alternating insulative tiers 20 and memory-cell tiers 22 above semiconductor material 14. Example memory-cell tiers 22 comprise memory cells MC and example insulative tiers 20 comprise insulative material 24 (e.g., silicon dioxide). Example memory cells MC individually comprise a horizontal transistor T and a capacitor C electrically coupled (e.g., directly) therewith. Horizontal transistor T comprises a gate 30* (e.g., conductive metal material) that is part of one of a plurality of horizontal conductive access lines WL* that individually directly electrically couple together multiple of gates 30* of different ones of horizontal transistors T that are in the same memory-cell tier 22 (an * being used as a suffix to be inclusive of all such same-numerically-designated structures or portions thereof that may or may not have other suffixes). Gate 30* comprises a top gate 30t and a bottom gate 30b having a channel region 28 vertically there-between. Top gate 30t is part of one of a plurality of top horizontal access lines WLt and bottom gate 30b is part of one of a plurality of bottom horizontal access lines WLb. Individual top and bottom access lines WLt and WLb, respectively, are horizontally elongated in a horizontal x-direction and are laterally spaced from one another in a horizontal y-direction that is perpendicular to x-direction. Insulative material 24 of insulative tiers 20 is vertically between top access line WLt and bottom access line WLb of immediately-vertically-adjacent the memory-cell tiers 22 (there being no other such noun [tier] between those that are immediately-adjacent one another). Intervening region 19 is laterally between two memory-array regions 10 in the x-direction.

Example horizontal transistor T comprises a first source/drain region 23 (e.g., conductively-doped silicon), a second source/drain region 26 (e.g., conductively-doped silicon), with channel region 28 being horizontally there-between. Regions 23 and 26 of different immediately-horizontally-adjacent memory cells MC into and out of the plane of the page upon which FIG. 3 lies in a common memory-cell tier 22 (e.g., in the x-direction) may be isolated relative one another by insulative material (not shown). A gate insulator 32 (e.g., dielectric or ferroelectric) is vertically between each of the respective top and bottom gates 30t and 30b and channel region 28. An example insulator material 40 (e.g., silicon nitride) is laterally against lateral sides/edges of gates 30*.

Example capacitor C comprises a storage-node electrode 33, a common electrode 34 (e.g., comprising conductive metal material 70 and conductively-doped polysilicon 71) that is common (directly electrically coupled) to a plurality of capacitors C (at least some, not necessarily all) of memory cells MC, and a capacitor insulator 36 there-between (e.g., dielectric or ferroelectric). Storage-node electrode 33 is directly electrically coupled to first source/drain region 23 of transistor T. Conductively-doped semiconductive material (e.g., conductively-doped epitaxial silicon and not shown) may be between storage-node electrode 33 and first source/drain region 23 (e.g., and such may be considered as a part of either or both).

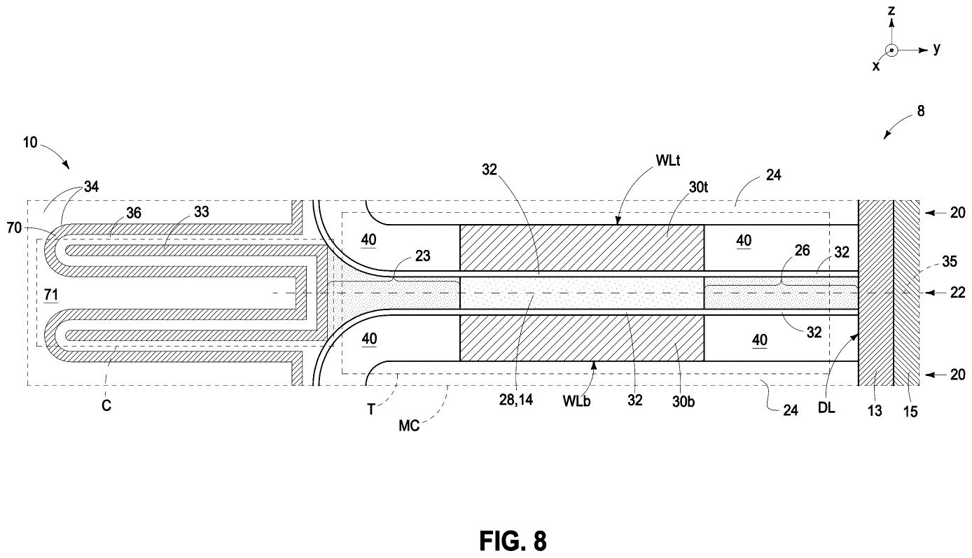

Digitlines DL (e.g., comprising conductive metal materials 13 and 15) extend through vertically-alternating tiers 20 and 22. Conductively-doped semiconductive material (not shown) may be between/proximate digitline DL and second source/drain region 26. Digitlines DL of different immediately-horizontally-adjacent memory cells MC running into and out of the plane of the page upon which FIG. 3 lies (in the x-direction) may be isolated/spaced relative one another by insulative material 24. Individual second source/drain regions 26 of individual transistors T that are in different memory-cell tiers 22 are electrically coupled (e.g., directly electrically coupled) to individual digitlines DL. Capacitor C and horizontal transistor T may be considered as being horizontally spaced relative one another along horizontal axis 35 (FIG. 8) along the y-direction. Dummy digitlines and dummy capacitors may be in intervening region 19.

Access lines WL* have x-direction ends 72 in intervening region 19. In one embodiment and as shown, ends 72 are planar and may be angled (other than the straight angle) relative to the y-direction (as shown) or may be parallel relative to the y-direction (not shown). An insulative wall 75 is in intervening region 19 and extends vertically through insulative tiers 20 and memory-cell tiers 22. Insulative wall 75 extends horizontally from and between x-direction ends 72 of immediately horizontally adjacent access lines WL*. Example insulative wall comprises insulative material 78 (e.g., silicon dioxide and/or silicon nitride) Insulative wall 75 has an elevationally-extending surface 77 (e.g., extending vertically) in individual of memory-cell tiers 22 that is horizontally concave between x-direction ends 72 of immediately-horizontally-adjacent access lines WL*. In one embodiment and as shown, at least some portion (only some or all, all being shown) of horizontally-concave-elevationally-extending surface 77 is horizontally curved and in one such embodiment (as shown) is horizontally curved along a constant radius. As alternate examples, only some part of surface 77 might not be concave, might include horizontal segments that are curved to/at different degrees, some or none of such curved segments being relative to a constant radius, include straight segments, include a combination or straight and curved segments, etc. (none of which are shown) while still being overall horizontally concave.

Embodiments of the invention encompass methods used in forming memory circuitry and, by way of example only, that may or may not incorporate device/structure as referred to above.

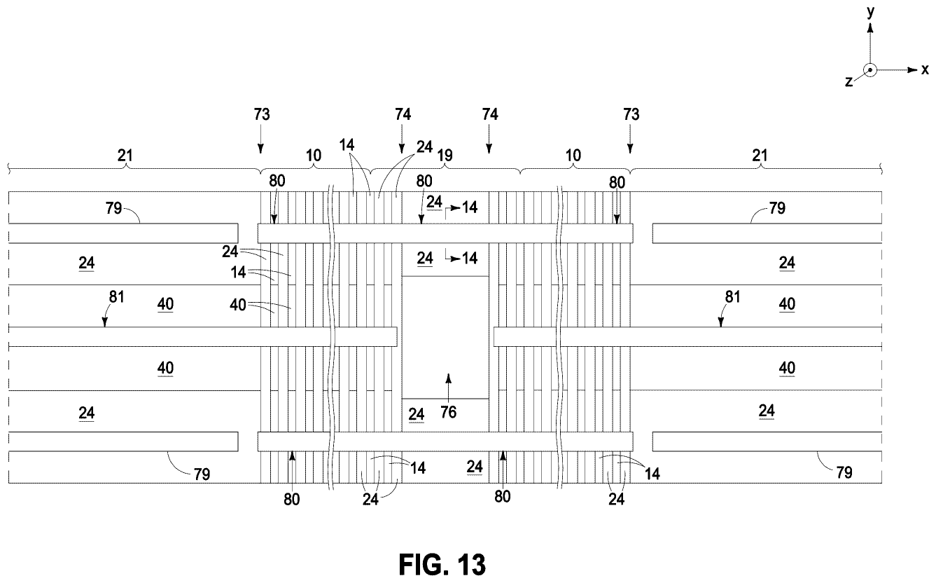

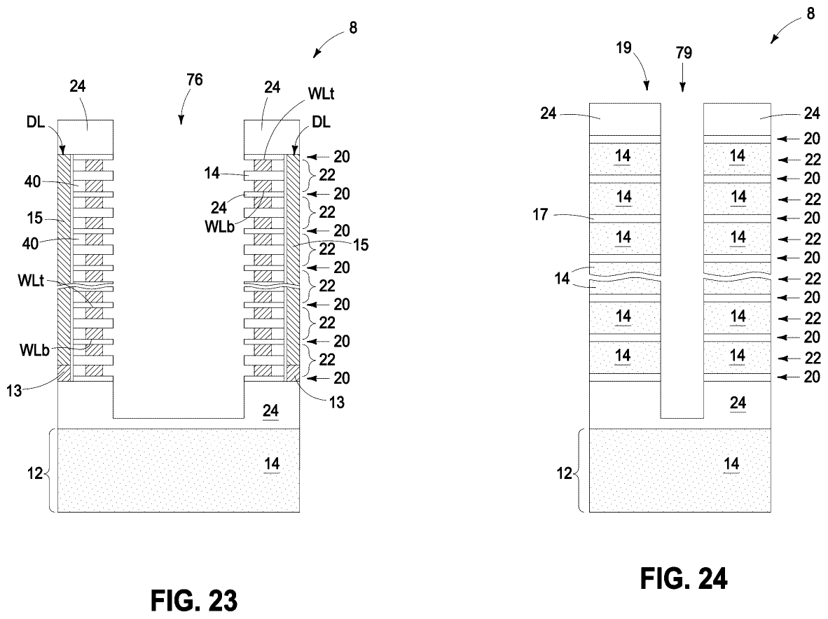

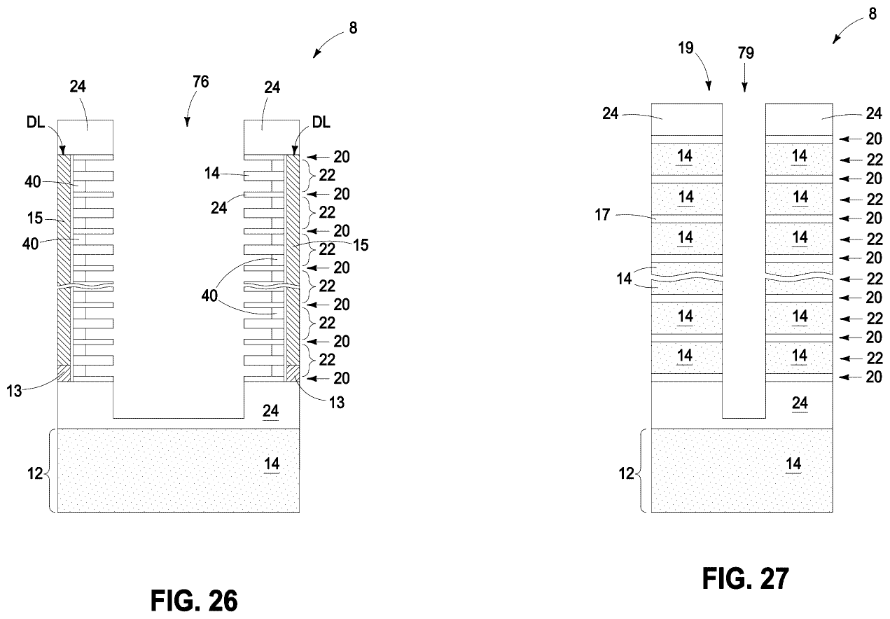

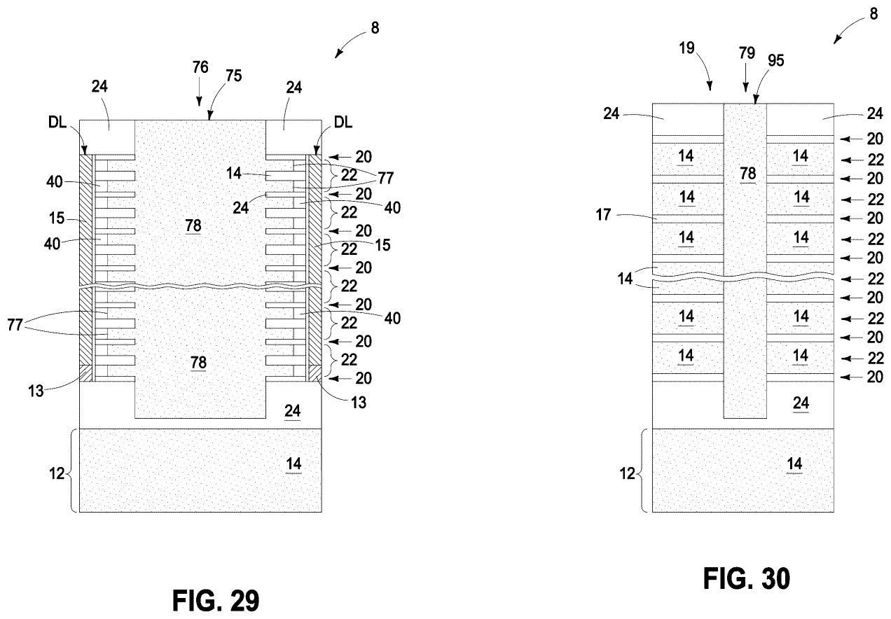

FIGS. 13-30 by way of example sequentially show predecessor constructions (e.g., diagrammatic to those of FIGS. 3-12) in an example method used in forming memory circuitry in accordance with embodiments of the invention. Such memory circuitry ultimately comprises vertically-stacked memory cells individually comprising a horizontal transistor and a capacitor electrically coupled (e.g., directly) therewith.

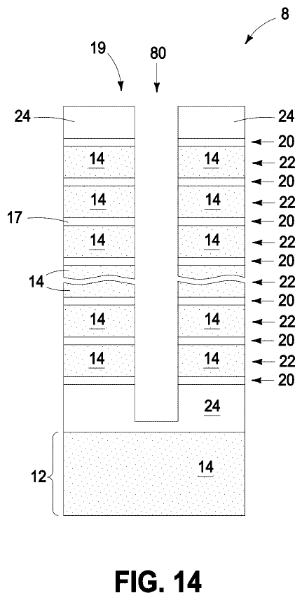

Referring to FIGS. 13 and 14, two memory-array regions 10 having an intervening region 19 laterally there-between in a horizontal x-direction have been formed as part of construction 8. Memory-array regions 10 may be considered as individually having opposite x-direction sides 73 and 74, with intervening region 19 being located on x-direction sides 74. A connection region 21 is adjacent each of two memory-array regions 10 on the opposite-x-direction side 73 from where intervening region 19 is located. In this document, a connection region is a region where conductive vias have been or will be formed to directly electrically couple to individual access lines that are in different memory-cell tiers. Example construction 8 in regions 10, 19, and 21 comprises first semiconductor material 14 (e.g., epitaxial monocrystalline silicon) and second material 17 that are of different compositions relative one another. An example second material 17 at least predominantly (more than 50% by volume up to and including 100% by volume) is silicon and germanium (e.g., an alloy of silicon and germanium).

In one embodiment and as shown, a first trench 76 has been formed vertically through vertically-alternating insulative and memory-cell tiers 20, 22 in intervening region 19. A second trench 79 (multiple being shown) has been formed vertically through vertically-alternating insulative and memory-cell tiers 20, 22 in connection regions 21. In some embodiments, second trenches 79 in the finished construction will be filled with insulative material and provide y-direction isolation between some immediately-y-direction-adjacent access lines WL*. First trench 76 may be elongated in the y-direction and second trench 79 may be elongated in the x-direction (both being shown). In one embodiment, a capacitor trench 80 (multiple being shown) has been formed vertically through vertically-alternating insulative and memory-cell tiers 20, 22 in each of two memory-array regions 10 (at least therein). In this document, a capacitor trench is a trench in which capacitors have been or will be formed. In one embodiment, a digitline trench 81 (multiple being shown) has been formed vertically through vertically-alternating insulative and memory-cell tiers 20, 22 in each of two memory-array regions 10 (at least therein). In this document, a digitline trench is a trench in which digitlines have been or will be formed. The various example trenches may be formed in any order relative one another, including some or all simultaneously.

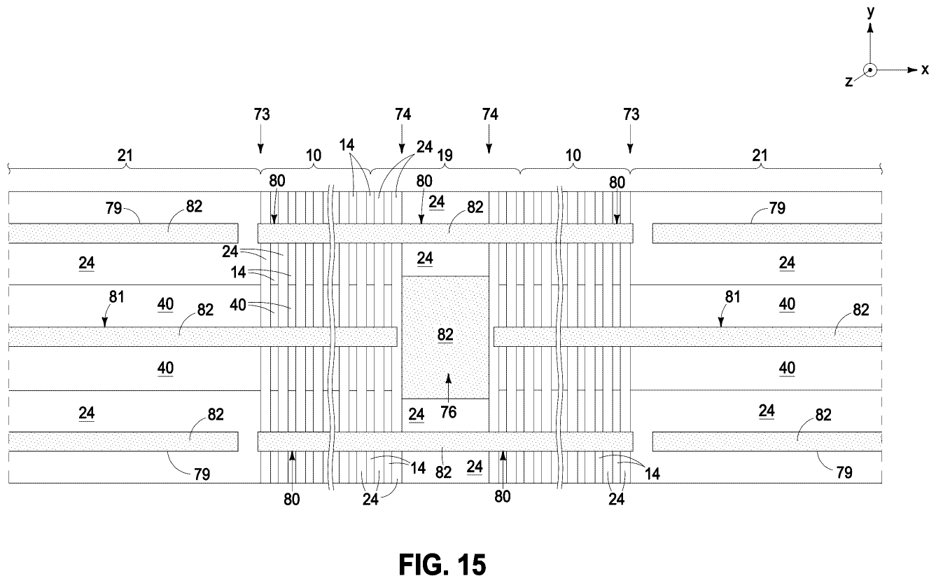

Referring to FIG. 15, first trench 76 and second trench 79 having been filled with sacrificial material 82 (e.g., carbon). In some embodiments and as shown, capacitor trench 80 and/or digitline trench 81 (when present) are also filled with sacrificial material 82, for example when filling first trench 76 and second trench 79 with sacrificial material 82.

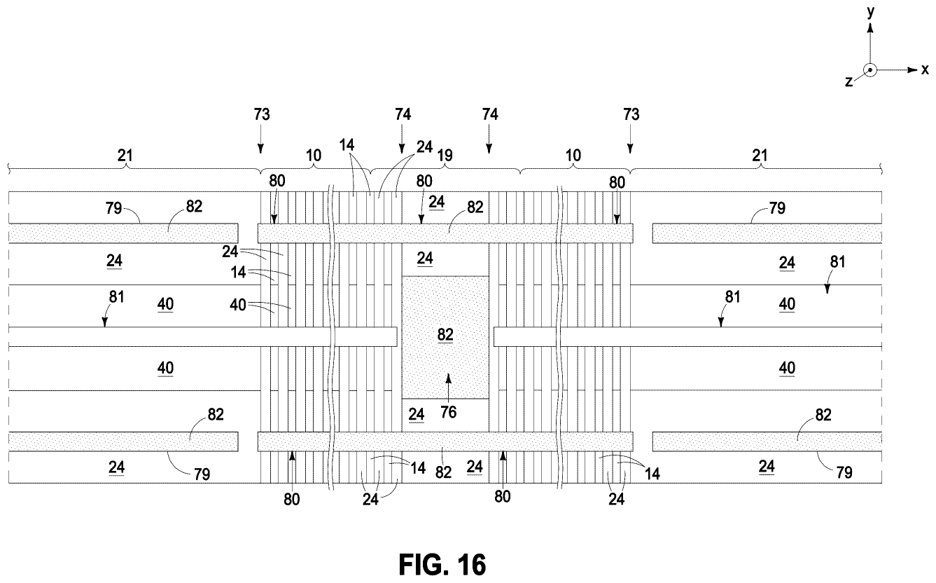

Referring to FIG. 16, digitline trenches 81 have been exposed (e.g., through a mask, not shown) while leaving trenches 76, 79 and 80 covered (e.g., by the mask, not shown), followed by removal of sacrificial material 82 from digitline trenches 81.

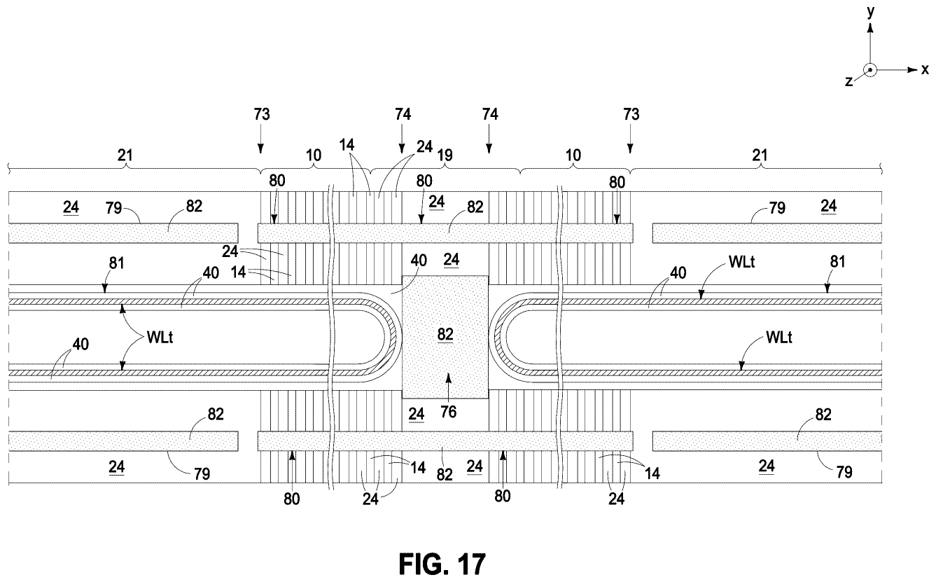

Referring to FIG. 17, lateral etching of second material 17 and thinning of first semiconductor material 14 has occurred relative to digitline trench 81 thereby widening such trench and access lines WL* have been formed in memory-cell tiers 22 and extend from two memory-array regions 10 into intervening region 19, all while first trench 76 and second trench 79 are filled with sacrificial material 82. Access lines WL* may also be formed while capacitor trenches 80 (if present) are filled with sacrificial material 82 as shown. Access lines WL* extend from memory-array regions 10 into connection regions 21 as shown. Access lines WL* are spaced from one another in the horizontal y-direction. Yet, immediately-horizontally-adjacent access lines WL* from individual of two memory-array regions 10 connect with one another in intervening region 19 as shown (e.g., loop around relative one another in mirror image as shown). First trench 76 is spaced in the x-direction from immediately-horizontally-x-direction adjacent access lines WL*. As shown, insulator material 40 may be formed in individual memory-cell tiers 22 before and after forming access lines WL*.

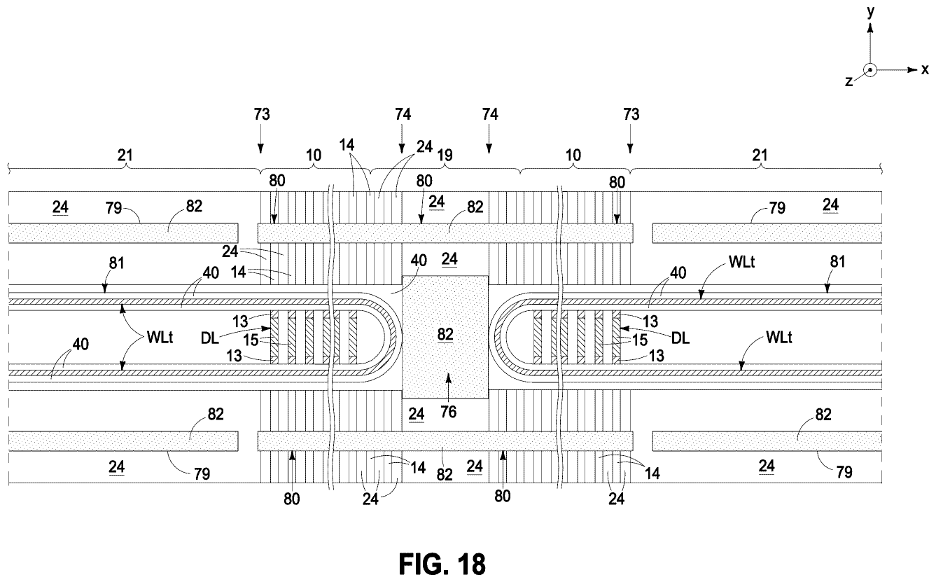

Referring to FIG. 18, digitlines DL have been formed in digitline trenches 81.

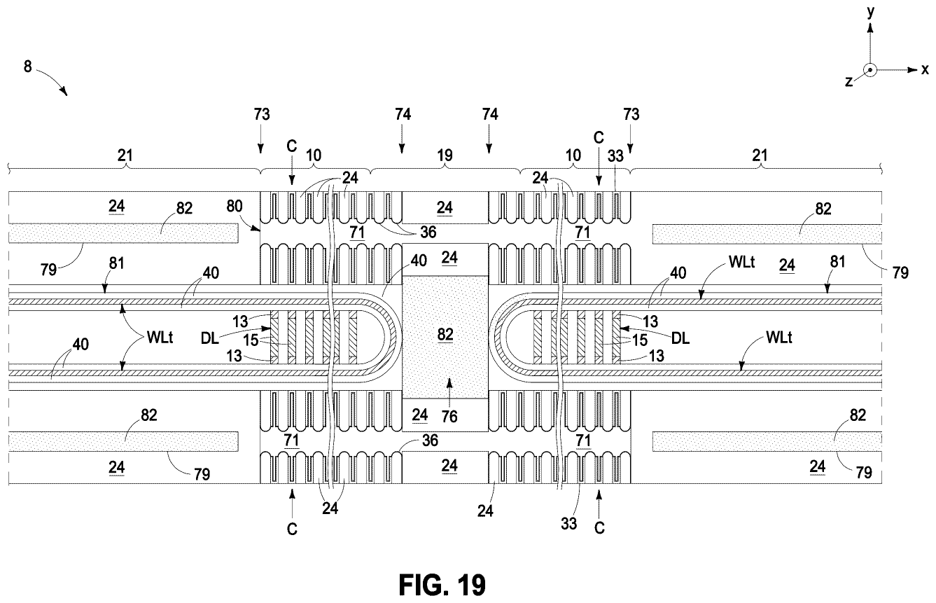

Referring to FIG. 19, sacrificial material 82 has been removed from capacitor trench 80 (shown in FIG. 18) while leaving sacrificial material 82 in first trench 76 and second trench 79. Then, in and through capacitor trench 80, capacitors C have been formed in each of memory array-regions 10 (at least) while sacrificial material 82 remains in first trench 76 and second trench 79. The digitlines, capacitors, and their respective trenches may be formed in any order relative the other.

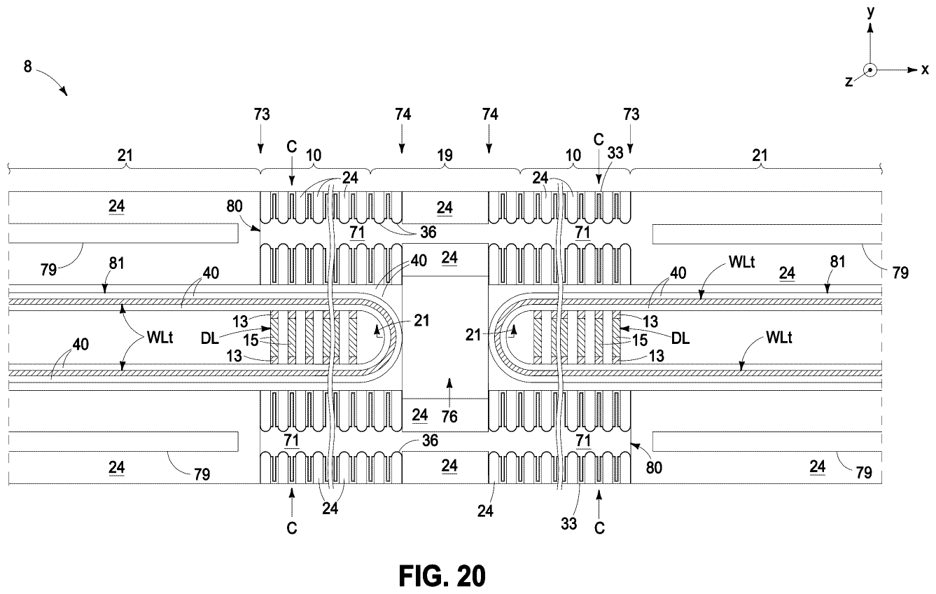

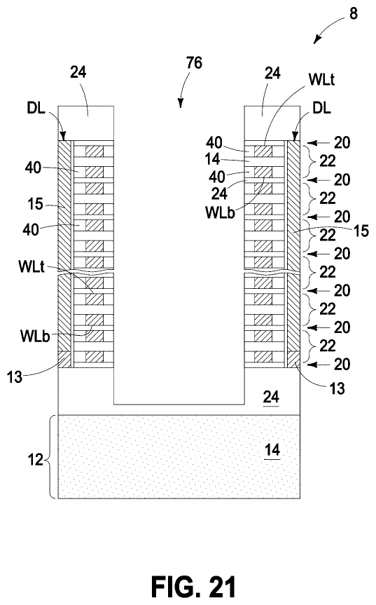

Referring to FIGS. 20 and 21, sacrificial material 82 has been removed from first trench 76 and second trench 79.

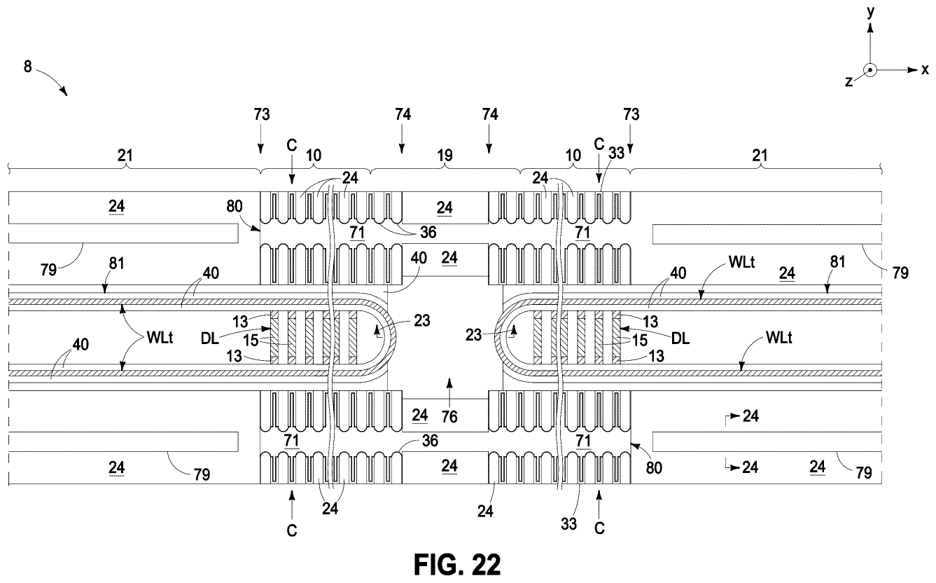

Referring to FIGS. 22-24, insulator material 40 (when present) that was laterally aside immediately-horizontally-adjacent access lines WL* has been etched away through first trench 76 (e.g., selectively relative to materials 24, 14, 17 and that of access lines WL*; e.g., using H₃PO₄ when insulator material 40 is silicon nitride).

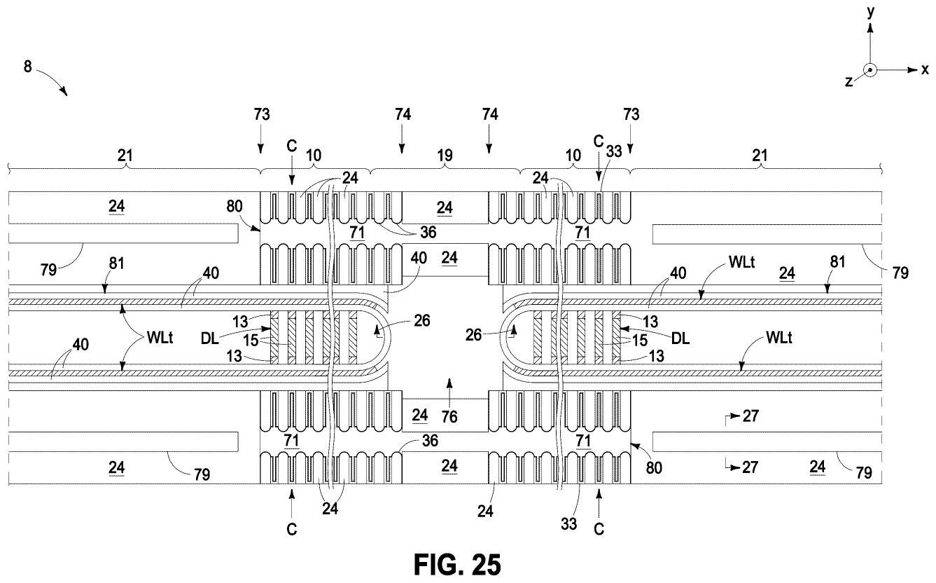

Referring to FIGS. 25-27, through first trench 76, etching has been conducted laterally through immediately-horizontally-adjacent access lines WL* to separate them from being connected with one another.

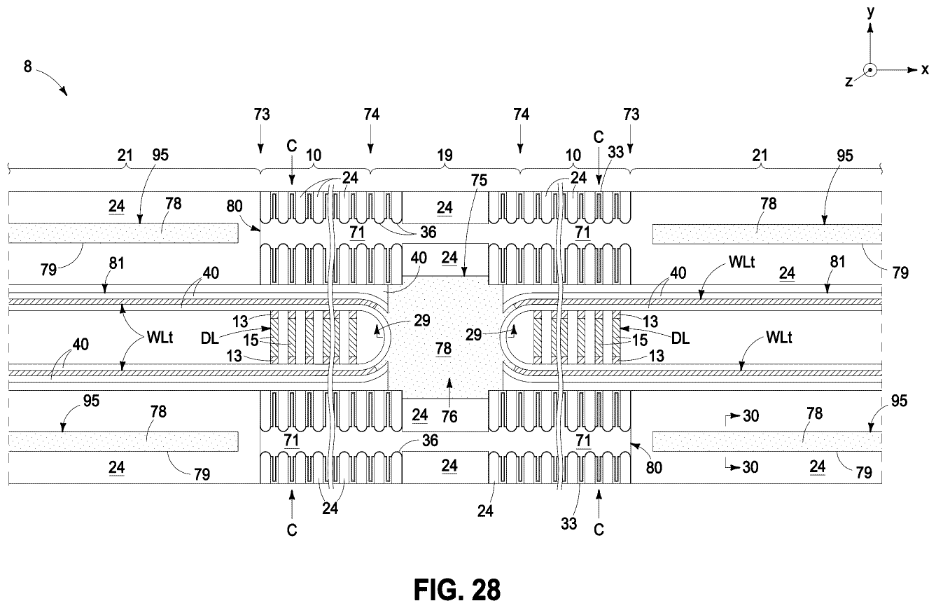

Referring to FIGS. 28-30, an insulative wall 75 comprising insulative material 78 and an insulative wall 95 comprising insulative material 78 have simultaneously been formed in first trench 76 and in second trench 79, respectively. Insulative wall 75 in the horizontal y-direction may extend horizontally beyond each of the immediately-horizontally-adjacent access lines WL*, for example as shown.

Any other attribute(s) or aspect(s) as shown and/or described herein with respect to other embodiments may be used.

In one embodiment, a method used in forming memory circuitry (e.g., that of or comprising construction 8) comprises forming two memory-array regions (e.g., 10) individually comprising vertically-alternating insulative tiers (e.g., 20) and memory-cell tiers (e.g., 22). An intervening region (e.g., 19) is laterally between the two memory-array regions in a horizontal x-direction. Access lines (e.g., WL*) are in the memory-cell tiers and extend from the two memory-array regions into the intervening region. The access lines are spaced from one another in a horizontal y-direction that is perpendicular the horizontal x-direction. Immediately horizontally adjacent of the access lines from individual of the two memory-array regions connect with one another in the intervening region. A trench (e.g., 76) extends vertically through the vertically-alternating insulative and memory-cell tiers in the intervening region. The trench is spaced from the immediately-horizontally-adjacent access lines in the x-direction. Through the trench, etching is conducted laterally through the immediately-horizontally-adjacent access lines to separate them from being connected with one another. After the etching, an insulative wall (e.g., 75) is formed in the trench. Any other attribute(s) or aspect(s) as shown and/or described herein with respect to other embodiments may be used.

In prior methods, etching was conducted vertically through access line stacks where the access lines horizontally connected with one another to break such connections and using a dedicated masking step when doing so. Such etching can be difficult and requires repeated changing of the etching chemistry depending on which material is being vertically etched through. Method aspects of the invention enable, although not require, etching laterally and thereby vertically through all of the access lines at the same time thereby reducing chemistry changes. In some embodiments, formation of the openings for such etching may be combined with the formation of other openings, for example in the formation of trenches in the connection regions, thereby reducing mask steps.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The circuitry described herein (e.g., conductive vias thereof) may connect with circuitry that is on either the top or the bottom (i.e., either z-axis side) of a vertical stack regardless of orientation of the construction in three-dimensional space and which is not material to aspects of the inventions disclosed herein. For example, and by way of example only, conductive vias may connect with peripheral control circuitry that is beneath the stack with respect to the orientation shown in the drawings. As an alternate example, and by way of example only, conductive vias may connect with peripheral control circuitry that is above the stack with respect to the shown orientation, for example to another substrate having such circuitry and that is bonded with the top of the stack with respect to the shown orientation. In such alternate example, the construction may be inverted from the shown orientation and then bonded with the other substrate. Further, in such alternate example, electronic components may be fabricated relative to the bottom of the stack with respect to the shown orientation but inverted there-from during processing. Such electronic components may connect with conductive vias that extend through the stack to the substrate bonded with the other side that has such peripheral control circuitry. Regardless, constructions as shown and described herein may be processed, packaged, and/or mounted in any three-dimensional spatial orientation.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication and as shown in drawings (if any) herein. Further, “vertical” and “horizontal” as used herein are generally perpendicular directions relative one another and independent of orientation of the substrate in three-dimensional space during fabrication and/or in a finished construction. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be conductive metal material and/or conductively-doped semiconductive/semiconductor/semiconducting material. “Metal material” is any one or combination of an elemental metal, any mixture or alloy of two or more elemental metals, and any one or more metallic compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### Conclusion

In some embodiments, a method used in forming memory circuitry comprises forming two memory-array regions individually comprising vertically-alternating insulative tiers and memory-cell tiers. An intervening region is laterally between the two memory-array regions in a horizontal x-direction. Access lines are in the memory-cell tiers and extend from the two memory-array regions into the intervening region. The access lines are spaced from one another in a horizontal y-direction that is perpendicular the horizontal x-direction. Immediately horizontally adjacent of the access lines from individual of the two memory-array regions connect with one another in the intervening region. A trench extends vertically through the vertically-alternating insulative and memory-cell tiers in the intervening region. The trench is spaced from the immediately-horizontally-adjacent access lines in the x-direction. Through the trench, etching is conducted laterally through the immediately-horizontally-adjacent access lines to separate them from being connected with one another. After the etching, an insulative wall is formed in the trench.

In some embodiments, a method used in forming memory circuitry comprises forming two memory-array regions individually comprising vertically-alternating insulative tiers and memory-cell tiers. An intervening region is laterally between the two memory-array regions in a horizontal x-direction. A connection region is adjacent each of the two memory-array regions on an opposite-x-direction side from where the intervening region is located. A first trench is formed vertically through the vertically-alternating insulative and memory-cell tiers in the intervening region and forms a second trench vertically through the vertically-alternating insulative and memory-cell tiers in the connection regions. The first and second trenches are filled with sacrificial material. Access lines are formed in the memory-cell tiers that extend from the two memory-array regions into the intervening region while the first and second trenches are filled with the sacrificial material. The access lines are spaced from one another in a horizontal y-direction that is perpendicular the horizontal x-direction. Immediately horizontally adjacent of the access lines from individual of the two memory-array regions connect with one another in the intervening region. The first trench is spaced from the immediately-horizontally-adjacent access lines in the x-direction. The sacrificial material is removed from the first and second trenches. After the removing and through the first trench, etching is conducted laterally through the immediately-horizontally-adjacent access lines to separate them from being connected with one another. After the etching, an insulative wall in the first trench and an insulative wall in the second trench are simultaneously formed.

In some embodiments, memory circuitry comprises two memory-array regions individually comprising vertically-alternating insulative tiers and memory-cell tiers. Access lines in the memory-cell tiers are horizontally elongated in a horizontal x-direction and spaced relative one another in a horizontal y-direction that is perpendicular the horizontal x-direction. An intervening region is laterally between the two memory-array regions in the horizontal x-direction. The access lines extend from the two memory-array regions into the intervening region. The access lines have x-direction ends in the intervening region. An insulative wall is in the intervening region and that extends vertically through the insulative and memory-cell tiers. The insulative wall extends horizontally from and between the x-direction ends of immediately horizontally adjacent of the access lines. The insulative wall has an elevationally-extending surface in individual of the memory-cell tiers that is horizontally concave between the x-direction ends of the immediately-horizontally-adjacent access lines.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. A method used in forming memory circuitry, comprising:
forming two memory-array regions individually comprising vertically-alternating insulative tiers and memory-cell tiers, an intervening region being laterally between the two memory-array regions in a horizontal x-direction, access lines in the memory-cell tiers that extend from the two memory-array regions into the intervening region, the access lines being spaced from one another in a horizontal y-direction that is perpendicular the horizontal x-direction, immediately horizontally adjacent of the access lines from individual of the two memory-array regions connecting with one another in the intervening region, a trench extending vertically through the vertically-alternating insulative and memory-cell tiers in the intervening region, the trench being spaced from the immediately-horizontally-adjacent access lines in the x-direction;
through the trench, etching laterally through the immediately-horizontally-adjacent access lines to separate them from being connected with one another; and
after the etching, forming an insulative wall in the trench.

2. The method of claim 1 wherein the trench is horizontally elongated in the horizontal y-direction.

3. The method of claim 1 wherein the trench and the insulative wall in the horizontal y-direction extend horizontally beyond at least one of the immediately-horizontally-adjacent access lines.

4. The method of claim 3 wherein the trench and the insulative wall in the horizontal y-direction extend horizontally beyond each of the immediately-horizontally-adjacent access lines.

5. The method of claim 1 comprising, through the trench, etching away insulator material that is laterally aside the immediately-horizontally-adjacent access lines before etching laterally through the immediately-horizontally-adjacent access lines.

6. The method of claim 1 sequentially comprising:
forming the trench before forming the access lines;
filling the trench with sacrificial material;
forming the access lines while the trench is filled with the sacrificial material;
removing the sacrificial material from the trench; and
conducting the etching after removing the sacrificial material.

7. The method of claim 6 comprising, through the trench, etching away insulator material that is laterally aside the immediately-horizontally-adjacent access lines before etching through the immediately-horizontally-adjacent access lines.

8. The method of claim 1 wherein the insulative wall extends horizontally from and between x-direction ends of the immediately-horizontally-adjacent access lines, the insulative wall having an elevationally-extending surface in individual of the memory-cell tiers that is horizontally concave between the x-direction ends of the immediately-horizontally-adjacent access lines.

9. A method used in forming memory circuitry, comprising:
forming two memory-array regions individually comprising vertically-alternating insulative tiers and memory-cell tiers, an intervening region being laterally between the two memory-array regions in a horizontal x-direction, a connection region adjacent each of the two memory-array regions on an opposite-x-direction side from where the intervening region is located;
forming a first trench vertically through the vertically-alternating insulative and memory-cell tiers in the intervening region and forming a second trench vertically through the vertically-alternating insulative and memory-cell tiers in the connection regions;
filling the first and second trenches with sacrificial material;
forming access lines in the memory-cell tiers that extend from the two memory-array regions into the intervening region while the first and second trenches are filled with the sacrificial material, the access lines being spaced from one another in a horizontal y-direction that is perpendicular the horizontal x-direction, immediately horizontally adjacent of the access lines from individual of the two memory-array regions connecting with one another in the intervening region, the first trench being spaced from the immediately-horizontally-adjacent access lines in the x-direction;
removing the sacrificial material from the first and second trenches;
after the removing and through the first trench, etching laterally through the immediately-horizontally-adjacent access lines to separate them from being connected with one another; and
after the etching, simultaneously forming an insulative wall in the first trench and an insulative wall in the second trench.

10. The method of claim 9 wherein the first trench is horizontally elongated in the y-direction.

11. The method of claim 9 wherein the second trench is horizontally elongated in the x-direction.

12. The method of claim 9 wherein,
the first trench is horizontally elongated in the y-direction; and
the second trench is horizontally elongated in the x-direction.

13. The method of claim 1 comprising:
forming a capacitor trench vertically through the vertically-alternating insulative and memory-cell tiers in the each of the two memory-array regions;
filling the capacitor trench with the sacrificial material when filling the first and second trenches with the sacrificial material; and
forming the access lines while the capacitor trench is filled with the sacrificial material.

14. The method of claim 13 sequentially comprising:
after forming the access lines, removing the sacrificial material from the capacitor trench and leaving the sacrificial material in the first and second trenches; and
through the capacitor trench in each of the memory-array regions, forming capacitors in each of the memory array-regions while the sacrificial material remains in the first and second trenches; the removing of the sacrificial material from the first and second trenches occurring after forming the capacitors.

15. The method of claim 9 wherein the insulative wall in the first trench in the horizontal y-direction extends horizontally beyond each of the immediately-horizontally-adjacent access lines.

16. The method of claim 9 wherein the insulative wall in the first trench extends horizontally from and between x-direction ends of the immediately-horizontally-adjacent access lines, the insulative wall in the first trench having an elevationally-extending surface in individual of the memory-cell tiers that is horizontally concave between the x-direction ends of the immediately-horizontally-adjacent access lines.

17. Memory circuitry comprising:
two memory-array regions individually comprising vertically-alternating insulative tiers and memory-cell tiers, access lines in the memory-cell tiers that are horizontally elongated in a horizontal x-direction and spaced relative one another in a horizontal y-direction that is perpendicular the horizontal x-direction;
an intervening region laterally between the two memory-array regions in the horizontal x-direction, the access lines extending from the two memory-array regions into the intervening region, the access lines having x-direction ends in the intervening region; and
an insulative wall in the intervening region that extends vertically through the insulative and memory-cell tiers, the insulative wall extending horizontally from and between the x-direction ends of immediately horizontally adjacent of the access lines, the insulative wall having an elevationally-extending surface in individual of the memory-cell tiers that is horizontally concave between the x-direction ends of the immediately-horizontally-adjacent access lines.

18. The memory circuitry of claim 17 wherein the x-direction ends of the access lines are planar.

19. The memory circuitry of claim 18 wherein the x-direction ends of the access lines are angled relative to the y-direction.

20. The memory circuitry of claim 18 wherein the x-direction ends of the access lines are parallel relative to the y-direction.

21. The memory circuitry of claim 17 wherein at least some portion of the horizontally-concave elevationally-extending surface is horizontally curved.

22. The memory circuitry of claim 21 wherein the horizontally-concave elevationally-extending surface of the portion is horizontally curved along a constant radius.

23. The memory circuitry of claim 21 wherein all of the horizontally-concave elevationally-extending surface is horizontally curved.
